(19) United States
(12) Patent Application Publication
(10) Pub. No.: US 2025/0338535 A1
(43) Pub. Date: Oct. 30, 2025

(54) SEMICONDUCTOR DEVICE AND METHOD OF FORMING THE SAME

(71) Applicant: Vanguard International Semiconductor Corporation, Hsinchu (TW)

(72) Inventors: Shin-Cheng LIN, Tainan City (TW); Cheng-Wei CHOU, Taoyuan City (TW); Hsiu-Ming WU, New Taipei City (TW); Jun-Han LIN, Taichung City (TW); Chia-Ching HUANG, Taoyuan City (TW)

(73) Assignee: Vanguard International Semiconductor Corporation, Hsinchu (TW)

(21) Appl. No.: 18/651,253

(22) Filed: Apr. 30, 2024

(51) Int. Cl. H01L 29/778; H01L 29/20; H01L 29/417; H01L 29/66

(52) U.S. Cl. CPC H10D 30/475; H10D 30/015; H10D 62/8503; H10D 64/256

(57) ABSTRACT

A semiconductor device and a method of forming the same are provided. The semiconductor includes a substrate, a buffer layer, a channel layer, a burrier layer, a first compound semiconductor layer, a second compound semiconductor layer, a gate metal, a first passivation layer, and a second passivation layer. The buffer layer is disposed on the substrate. The channel layer is disposed on the buffer layer. The burrier layer is disposed on the channel layer. The first compound semiconductor layer is disposed on the barrier layer. The second compound semiconductor layer is disposed on the first compound layer. The gate metal is disposed on the second compound semiconductor layer. The first passivation layer is disposed on the first compound semiconductor layer, the second compound semiconductor layer, and the gate metal. The second passivation layer is disposed on the first passivation layer.

### BACKGROUND OF THE INVENTION

### Field of the Invention

The present invention relates to a semiconductor device and a method of forming the same, and in particular, to a high electron mobility transistor and a method of forming the same.

### Description of the Related Art

Gallium nitride (GaN) is a material that possesses various excellent properties and hence is widely used. For example, gallium nitride has a wide band-gap, high thermal resistance, and high electron saturation velocity. In addition, gallium nitride also has extremely strong polarization effects. Besides the spontaneous polarization caused by the lattice structure, lattice extrusion caused by lattice mismatch also leads to piezoelectric polarization. Due to the simultaneous presence of these two polarization effects, the gallium nitride material will generate extremely large polarization charges at the heterojunction.

In view of the excellent characteristics of gallium nitride materials mentioned above, gallium nitride-based semiconductors have been widely used in high electron mobility transistors (HEMTs) containing heterojunction structures.

High electron mobility transistors may be affected during the manufacturing process (such as etching processes, high temperature environments), resulting in poor electrical performance or uniformity. Although existing high electron mobility transistors have generally been adequate for their intended purposes, they have not been satisfactory in all respects.

### BRIEF SUMMARY OF THE INVENTION

An embodiment of the present invention provides a semiconductor device. The semiconductor device includes a substrate. The semiconductor device includes a buffer layer disposed on the substrate. The semiconductor device includes a channel layer disposed on the buffer layer. The semiconductor device includes a barrier layer disposed on the channel layer. The semiconductor device includes a first compound semiconductor layer disposed on the barrier layer. The semiconductor device includes a second compound semiconductor layer disposed on the first compound layer. The semiconductor device includes a gate metal disposed on the second compound semiconductor layer. The semiconductor device includes a first passivation layer disposed on the first compound semiconductor layer, the second compound semiconductor layer and the gate metal. The semiconductor device includes a second passivation layer disposed on the first passivation layer.

In addition, an embodiment of the present invention provides a method of forming a semiconductor device. The method includes providing a substrate. A buffer layer, a channel layer, and a barrier layer are sequentially formed on the substrate. The method includes forming a first compound semiconductor layer on the barrier layer. The method includes forming a second compound semiconductor material layer on the first compound semiconductor layer. The method includes etching the second compound semiconductor material layer to form a second compound semiconductor layer. The method includes forming a gate metal on the second semiconductor layer. The method includes forming a first passivation layer on the first compound semiconductor layer, the second compound semiconductor layer, and the gate metal. The method includes forming a second passivation layer on the first passivation layer.

### BRIEF DESCRIPTION OF THE DRAWINGS

Aspects of the present disclosure are best understood from the following detailed description when read with the accompanying figures. It should be emphasized that, in accordance with the standard practice in the industry, various features are not drawn to scale. In fact, the dimensions of the various features may be arbitrarily increased or reduced for clarity of discussion.

FIGS. 1-9 show the cross-sectional views of various stages of a process for forming a semiconductor device, in accordance with some embodiments.

FIG. 10 shows the cross-sectional views of various stages of a process for forming a semiconductor device, in accordance with some other embodiments.

### DETAILED DESCRIPTION OF THE INVENTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “about” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

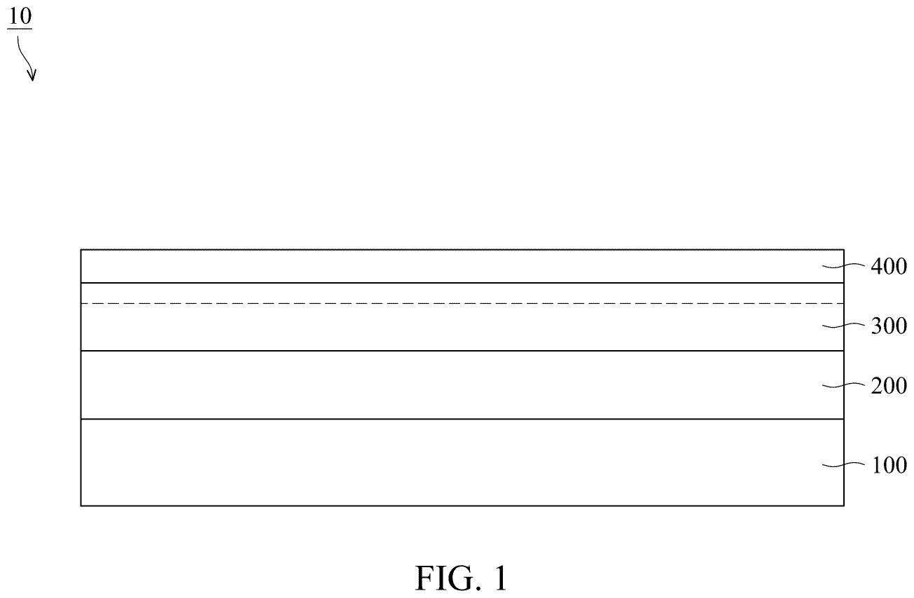

FIGS. 1-9 show the cross-sectional views of various stages of a process for forming a semiconductor device, in accordance with some embodiments.

Referring to FIG. 1, a substrate 100 is provided, on which a buffer layer 200, a channel layer 300, and a barrier layer 400 is formed. The buffer layer 200 may be disposed on the substrate 100. The channel layer 300 may be disposed on the buffer layer 200 and the substrate 100, that is, the buffer layer 200 may be disposed between the substrate 100 and the channel layer 300. The barrier layer 400 may be disposed on the channel layer 300.

In some embodiments, the substrate 100 may be a semiconductor on insulator substrate, such as silicon on insulator (SOI) or silicon germanium on insulator (SGOI). In other embodiments, the substrate 100 may be a silicon (Si) substrate or a ceramic substrate, such as an aluminum nitride (AlN) substrate, a silicon carbide (SiC) substrate, an aluminum oxide (Al₂O₃) substrate (also known as a sapphire substrate), a glass substrate, or other similar substrate. In some embodiments, the substrate 100 may include a ceramic substrate and a pair of barrier layers disposed respectively on the upper and lower surfaces of the ceramic substrate, wherein the ceramic substrate may include a ceramic material, and the ceramic material may include a metal inorganic material. For example, the ceramic substrate may include silicon carbide, aluminum nitride, sapphire substrate, or other suitable materials. The aforementioned sapphire substrate may be alumina.

The lattice or the thermal expansion coefficient of the substrate 100 may be different from that of the upper component (such as the channel layer 300). Therefore, strain may occur at or near the interface between the substrate 100 and the upper component, which may lead to defects such as cracks or warpage easily. Therefore, as shown in FIG. 1, the buffer layer 200 may be formed on the substrate 100 to reduce the strain of components (such as the channel layer 300) formed above the buffer layer 200 and to prevent defects forming in the components above.

In some embodiments, the material of the buffer layer 200 may include III-V compound semiconductor materials, such as III-nitrides and the like. For example, the material of the buffer layer 200 may be or include gallium nitride, aluminum nitride, aluminum gallium nitride (AlGaN), aluminum indium nitride (AlInN), any other suitable material, or a combination thereof. In some embodiments, the buffer layer 200 may be a multi-layer structure (not shown). For example, the buffer layer 200 may include a superlattice buffer layer and/or a gradient buffer layer, wherein the superlattice buffer layer is disposed on the substrate 100 and the gradient buffer layer is disposed on the superlattice buffer layer. It can prevent dislocation within the substrate 100 from entering the components above effectively and can further improve the crystal quality of other films and/or layers above. In some embodiments, the thickness of the buffer layer 200 may be, for example, 0.5 microns to 10 microns, such as about 3 microns.

In some embodiments, the buffer layer 200 can be formed by an epitaxial growth process, such as chemical vapor deposition, physical vapor deposition, etc., more specifically, such as metal organic chemical vapor deposition (MOCVD), hydride vapor phase epitaxy (HVPE), molecular beam epitaxy (MBE), atomic layer deposition (ALD), liquid phase epitaxy (LPE), other suitable methods, or a combination thereof.

In some embodiments, a seed layer (not shown) may be formed between the substrate 100 and the buffer layer 200 as required. In these embodiments, the seed layer can alleviate the lattice difference between the substrate 100 and the film and/or layer grown above to improve crystal quality. The material of the seed layer may include AlN, Al₂O₃, AlGaN, SiC, Al, other similar materials, or a combination of the thereof. The seed layer with single-layer or multi-layer structure may be formed by a suitable process, such as chemical vapor deposition, physical vapor deposition, etc., more specifically, such as metal-organic chemical vapor deposition (MOCVD), hydride vapor phase epitaxy (HVPE), molecular beam epitaxy (MBE), atomic layer deposition (ALD), liquid phase epitaxy (LPE), other suitable methods, or a combination thereof. In some embodiments, the material of the buffer layer 200 depends on the material of the seed layer and the gas introduced during the epitaxial process.

The channel layer 300 is formed on the buffer layer 200. In some embodiments, the material of the channel layer 300 includes III-V compound semiconductor materials, such as III-nitride and the like. In some embodiments, the material of the channel layer 300 may be gallium nitride (GaN), AlGaN, AlN, GaAs, GaInP, AlGaAs, InP, InAlAs, InGaAs, any other suitable materials, or a combination thereof. In some embodiments, channel layer 300 may be undoped. In some embodiments, channel layer 300 may be doped with n-type dopants or p-type dopants. The channel layer 300 may include a single layer or a multi-layer structure. In some embodiments, the thickness of channel layer 300 may range from about 0.01 microns (μm) to about 10 μm. The channel layer 300 may be formed by an epitaxial growth process, such as metal organic chemical vapor deposition, hydride vapor phase epitaxy, molecular beam epitaxy, atomic layer deposition, liquid phase epitaxy, a combination thereof, or the like.

The barrier layer 400 is formed on the channel layer 300. In some embodiments, the material of the barrier layer 400 may include III-V compound semiconductor, such as a III-nitride or the like. In some embodiments, the barrier layer 400 may be GaN, AlGaN, AlN, GaAs, GaInP, AlInN, AlGaAs, InP, InAlAs, InGaAs, other suitable materials, or a combination thereof, but is not limited thereto. In some embodiments, barrier layer 400 may be undoped. In some embodiments, barrier layer 400 may be doped with n-type dopants or p-type dopants. The barrier layer 400 may include a single layer or a multi-layer structure. In some embodiments, barrier layer 400 may have a thickness ranging from, for example, about 1 nanometer to about 100 nanometers.

In some embodiments, the barrier layer 400 may be formed by an epitaxial growth process, such as metal organic chemical vapor deposition, hydride vapor phase epitaxy, molecular beam epitaxy, atomic layer deposition, liquid phase epitaxy, a combination thereof, or the like. In some embodiments, the material of the channel layer 300 and that of the barrier layer 400 may be different, and their interface may be a heterojunction structure. The lattice mismatch between the channel layer 300 and the barrier layer 400 may result in stress generation which leads to piezoelectric polarization effect. Besides, the bonding between Group III metals (such as Al, Ga, or In) and nitrogen is more ionic, resulting in spontaneous polarization. Because of the different energy gaps between the channel layer 300 and the barrier layer 400, and the piezoelectric polarization and spontaneous polarization effects mentioned above, two-dimensional electron gas (2DEG) is formed at the heterointerface between the channel layer 300 and the barrier layer 400, as shown by the dotted line in FIG. 1. In some embodiments, the two-dimensional electron gas channel is used to provide conductive carriers for the subsequently formed high electron mobility transistor, so it can serve as a current path.

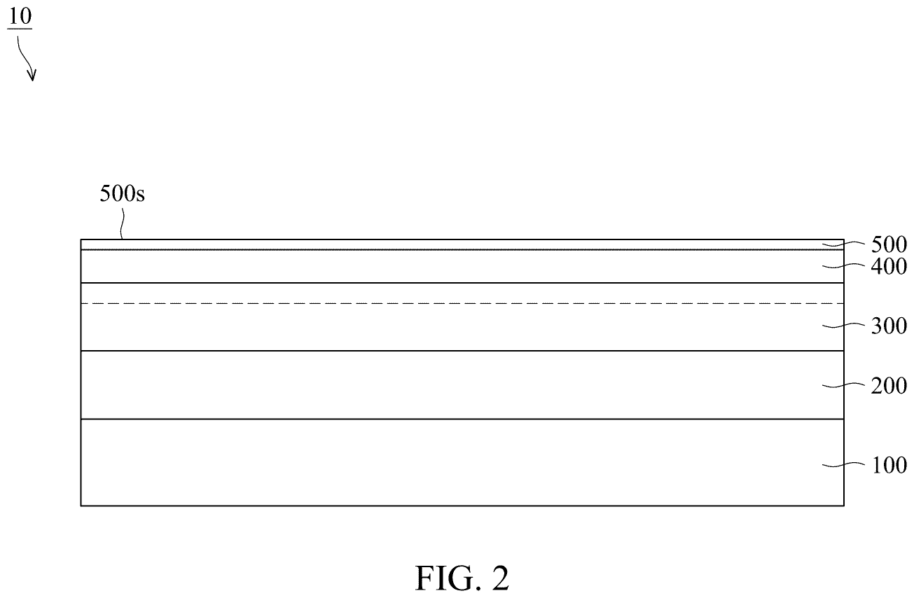

Next, referring to FIG. 2, a first compound semiconductor layer 500 may be formed on the barrier layer 400, where the first compound semiconductor layer 500 has a surface 500s. In some embodiments, the first compound semiconductor layer 500 may be undoped gallium nitride (uGaN). In some embodiments, the first compound semiconductor layer 500 may include undoped AlGaN, AlN, GaAs, GaInP, AlGaAs, InP, InAlAs, InGaAs, other suitable III-V materials, or a combination thereof. The first compound semiconductor layer 500 may be used as an etch stop layer to protect the barrier layer 400 from being affected by etching during the subsequent etching process. In some embodiments, the thickness of the first compound semiconductor layer 500 may be 3 nm to 30 nm, for example, 5 nm to 28 nm, 8 nm to 25 nm, 10 nm to 23 nm, 13 nm to 20 nm, 15 to 18 nm.

In some embodiments, the first compound semiconductor layer 500 may be formed by an epitaxial growth process, such as metal organic chemical vapor deposition, hydride vapor phase epitaxy, molecular beam epitaxy, atomic layer deposition, liquid phase epitaxy, a combination thereof, or the like. In some embodiments, the first compound semiconductor layer 500 may be formed by high-temperature chemical vapor deposition at a temperature of 400° C. to 1500° C., such as 500° C. to 1400° C., 600° C. to 1300° C., 700° C. to 1200° C., 800° C. to 1100° C., 900° C. to 1000° C.

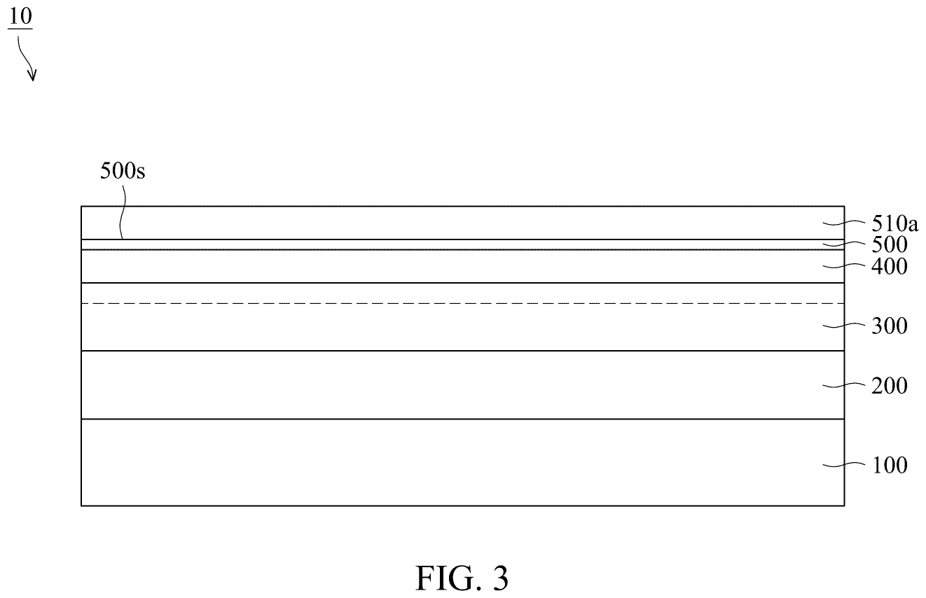

Next, referring to FIG. 3, a second compound semiconductor material layer 510a is formed on the first compound semiconductor layer 500. In some embodiments, the second compound semiconductor material layer 510a may be gallium nitride. In some other embodiments, the second compound semiconductor material layer 510a may include AlGaN, AlN, GaAs, GaInP, AlGaAs, InP, InAlAs, InGaAs, other suitable III-V materials, or a combination thereof. In some embodiments, the thickness of the second compound semiconductor material layer 510a may be, for example, 20 nm to 80 nm, such as 25 nm to 75 nm, 30 nm to 70 nm, 35 nm to 65 nm, 40 nm to 60 nm, 45 nm to 55 nm, etc. In some embodiments, the second compound semiconductor material layer 510a may be formed by, for example, a deposition process, such as metal organic chemical vapor deposition, hydride vapor phase epitaxy, molecular beam epitaxy, atomic layer deposition, liquid phase epitaxy, a combination thereof, or the like.

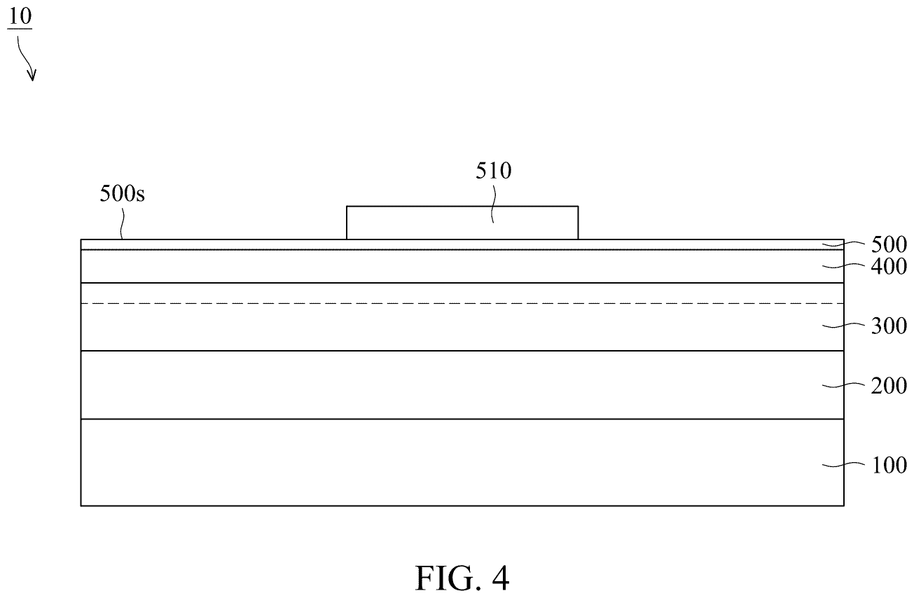

Next, as shown in FIG. 4, the second compound semiconductor material layer 510a is patterned and doped to form a second compound semiconductor layer 510. The second compound semiconductor material layer 510a may be doped before or after patterning. In some embodiments, the second compound semiconductor layer 510 may be p-type doped or n-type doped, and the doping concentration may be 1e15/cm³ to 1e20/cm³, such as 5e15/cm³ to 5e19/cm³, 1e16/cm³ to 1e19/cm³, 5e16/cm³ to 5e18/cm³, 1e17/cm³ to 1e18/cm³.

For instance, the above-mentioned patterning process may include photolithographic processes (for example, photoresist coating, soft baking, mask aligning, exposure, post-exposure baking, photoresist development, another appropriate process, or a combination thereof), etching processes (for example, wet etching process, dry etching process, another appropriate process, or a combination thereof), another appropriate process, or a combination thereof. According to some embodiments, a patterned mask layer (not shown) is formed on the second compound semiconductor material layer 510a, and then the second compound semiconductor material layer 510a is etched to remove the portion uncovered by the patterned mask layer to form a second compound semiconductor layer 510. The position of the second compound semiconductor layer 510 may be adjusted according to the predetermined position of the gate. In some embodiments, the second compound semiconductor layer 510 can inhibit the two-dimensional electron gas channel underneath it; therefore, the safety concerns of the conventional normally-on state can be overcome by achieving a normally-off state in the subsequently formed semiconductor device 10.

In some embodiments, the patterned mask layer may be a photoresist, such as a positive photoresist or a negative photoresist. In other embodiments, the patterned mask layer may be a hard mask, such as silicon oxide, silicon nitride, silicon oxynitride, silicon carbide, silicon nitride carbide, similar materials, or a combination thereof. In some embodiments, the patterned mask layer may be formed by spin coating, physical vapor deposition, chemical vapor deposition, similar processes, or a combination thereof.

In some embodiments, the second compound semiconductor material layer 510a may be etched by a dry etching process, a wet etching process, or a combination thereof. For example, the etching of the second compound semiconductor material layer 510a includes reactive ion etching (RIE), inductively-coupled plasma (ICP) etching, neutral beam etching (NBE), electron cyclotron resonance (ERC) etching, similar etching processes, or a combination thereof. In addition, although the second compound semiconductor layer 510 has substantially vertical sidewalls and a flat upper surface as shown in the figures, the invention is not limited thereto. The second compound semiconductor layer 510 may also have other shapes, such as inclined sidewalls and/or an uneven upper surface. In some embodiments, the etching of the second compound semiconductor material layer 510a stops at the surface 500s of the first compound semiconductor layer 500. That is, the first compound semiconductor layer 500 is used as the etch stop layer in the etching step of the second compound semiconductor material layer 510a.

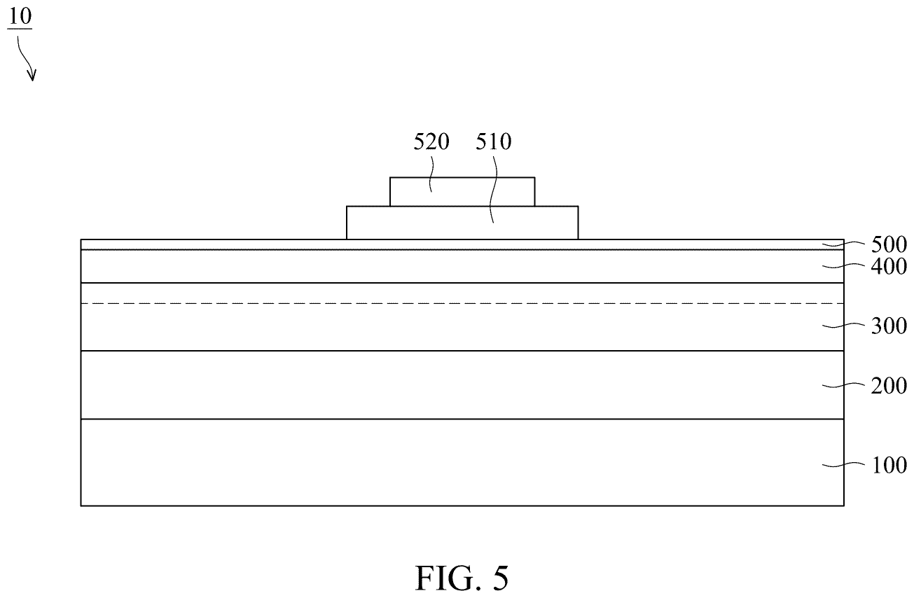

Referring to FIG. 5, a gate metal 520 is formed above the second compound semiconductor layer 510. In some embodiments, the material of the gate metal 520 includes conductive materials, such as aluminum (Al), copper (Cu), tungsten (W), titanium (Ti), tantalum (Ta), titanium nitride (TiN), tantalum nitride (TaN), nickel silicide (NiSi), cobalt silicide (CoSi), tantalum carbide (TaC), tantalum silicide nitride (TaSiN), tantalum carbide nitride (TaCN), titanium aluminide (TiAl), titanium aluminum nitride (titanium aluminide nitride, TiAlN), metal oxides, metal alloys, other suitable conductive materials or a combination thereof.

In some embodiments, the formation of the gate metal 520 includes depositing a conductive material over the second compound semiconductor layer 510 and then performing a patterning process on the deposited conductive material to form the gate metal 520. The conductive material may be deposited by, for example, chemical vapor deposition, physical vapor deposition (such as evaporation or sputtering), electroplating, atomic layer deposition, another appropriate method, or a combination thereof. The patterning process may include photolithography process, etching process, another appropriate process, or a combination thereof. Specific reference can be made to the patterning of the second compound semiconductor material layer 510a, which will not be repeated herein.

In some embodiments, the second compound semiconductor layer 510 and the gate metal 520 may be formed by depositing the second compound semiconductor material layer and the gate metal material layer then performing appropriate etching.

Due to the easily oxidized nature of the gate metal, it is difficult to maintain the gate leakage current (I_{g}) and 2DEG sheet resistance (R_{SH}) of the semiconductor device within the desired range by previous manufacturing process. Therefore, by disposing a thin passivation layer on the gate metal at low temperature, the present disclosure can prevent the gate metal from oxidizing in the subsequent high-temperature process environment and prevent the rising of the gate resistance.

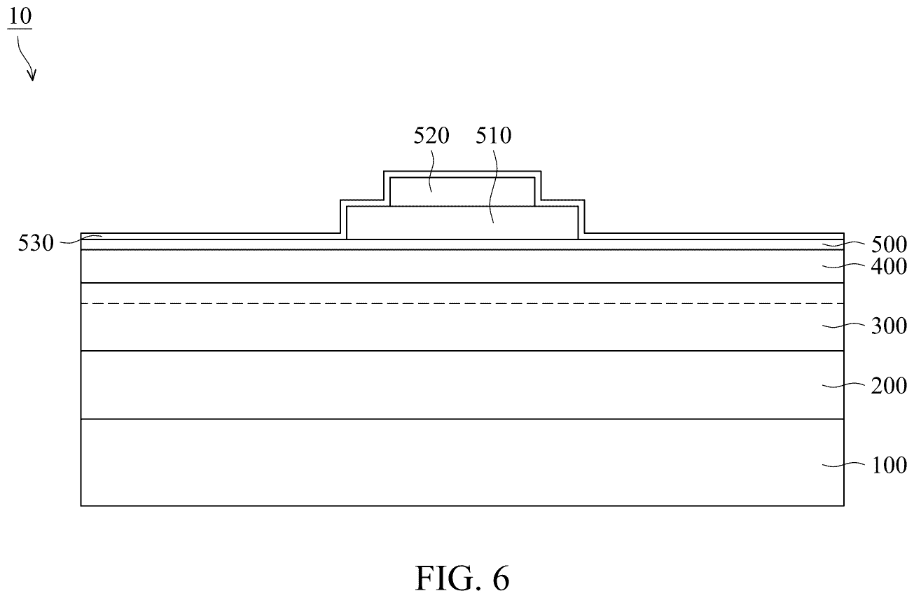

Referring to FIG. 6, a first passivation layer 530 is disposed on the semiconductor device 10. The first passivation layer 530 may be formed on the first compound semiconductor layer 500, the second compound semiconductor layer 510, and the gate metal 520. In other words, the first passivation layer 530 may be disposed between the first compound semiconductor layer 500, the second compound semiconductor layer 510, and the gate metal 520 and the subsequently formed second passivation layer. The first passivation layer 530 may include, for example, silicon oxide (SiOₓ), silicon nitride (SiₓN_{y}), silicon oxynitride (SiOₓN_{y}), aluminum oxide (AlOₓ), aluminum nitride (AlN), polyimide (PI), benzocyclobutene (BCB), polybenzoxazole (PBO), tetraethoxysilane (TEOS) oxide, phosphosilicate glass (PSG), borophosphosilicate borophosphosilicate glass (BPSG), other insulating materials, or a combination thereof. The first passivation layer 530 may be a single layer film or a multi-layer film. The first passivation layer 530 may have a thickness of 3 Å to 200 Å, such as 5 Å to 180 Å, 10 Å to 160 Å, 15 Å to 140 Å, 20 Å to 120 Å, 25 Å to 100 Å, 30 Å to 80 Å, 35 Å to 75 Å, 40 Å to 70 Å, 45 Å to 65 Å, 50 Å to 60 Å, etc.

In some embodiments, the first passivation layer 530 may have a flat surface. In some embodiments, the first passivation layer 530 may have a stepped surface. The shape of the above-mentioned stepped surface corresponds to the shape of the first compound semiconductor layer 500, the second compound semiconductor layer 510, and the gate metal 520. That is, the first passivation layer 530 is formed conformally, or blanketly on the surfaces of the first compound semiconductor layer 500, the second compound semiconductor layer 510, and the gate metal 520. It should be noted that the stepped surface of the first passivation layer 530 shown in FIG. 6 is merely an example and is not intended to be limiting. That is, the shape of the first passivation layer 530 is not limited to that in FIG. 6. In some embodiments, the corners of the stepped surface of the first passivation layer 530 may be acute angles, right angles, rounded angles, obtuse angles, or any suitable shapes. In some embodiments, the first passivation layer 530 may have any shapes corresponding to the height difference of the surfaces of the first compound semiconductor layer 500, the second compound semiconductor layer 510, and the gate metal 520, that is, the first passivation layer 530 may have the shape corresponding to the step.

In some embodiments, the first passivation layer 530 may be formed by a deposition process, such as plasma-enhanced chemical vapor deposition (PECVD), atomic layer deposition, high-density plasma chemical vapor deposition (high-density plasma chemical vapor deposition, HDPCVD), other suitable processes, or a combination thereof. In some embodiments, the first passivation layer 530 may be deposited at a temperature from 40° C. to 400° C., such as 50° C. to 390° C., 60° C. to 380° C., 70° C. to 370° C., 80° C. to 360° C., 90° C. to 350° C., 100° C. to 340° C., 110° C. to 330° C., 120° C. to 320° C., 130° C. to 310° C., 140° C. to 300° C., 150° C. to 290° C., 160° C. to 280° C., 170° C. to 270° C., 180° C. to 260° C., 190° C. to 250° C., 200° C. to 240° C., 210° C. to 230° C., 220° C. to 225° C. By forming the first passivation layer 530 at lower temperature, the gate metal 520 can be prevented from being oxidized due to subsequent high-temperature processes, so that the gate leakage current (I_{g}) and 2DEG sheet resistance (R_{SH}) of the semiconductor device can be maintained within the desired range, thereby obtaining a suitable semiconductor device on-resistance (Rₒₙ).

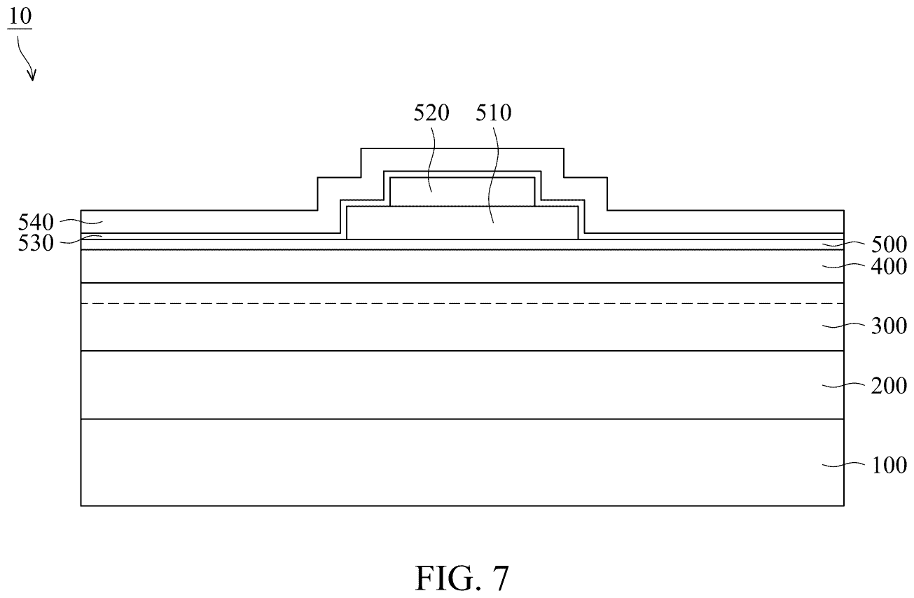

Next, as shown in FIG. 7, a second passivation layer 540 can be formed on the first passivation layer 530. The second passivation layer 540 may include, for example, silicon oxide, silicon nitride, silicon oxynitride, aluminum oxide, hafnium oxide, aluminum nitride, polyimide, phenylcyclobutene, polybenzoxazole, tetraethoxysilane oxide, phosphosilicate glass, boron phosphosilicate glass, other insulating materials, or a combination thereof. The second passivation layer 540 may be a single layer film or a multi-layer film. The second passivation layer 540 may have a thickness of 100 Å to 2000 Å, such as 150 Å to 1900 Å, 200 Å to 1800 Å, 250 Å to 1700 Å, 300 Å to 1600 Å, 350 Å to 1500 Å, 400 Å to 1400 Å, 450 Å to 1300 Å, 500 Å to 1200 Å, 550 Å to 1100 Å, 600 Å to 1000 Å, 650 Å to 900 Å, 700 Å to 850 Å, 750 Å to 800 Å, etc.

In some embodiments, the second passivation layer 540 may have a flat surface. In some embodiments, the second passivation layer 540 may have a stepped surface. The shape of the above-mentioned stepped surface corresponds to the shape of the first passivation layer 530, that is, it is conformally formed on the surface of the first passivation layer 530. It should be noted that the stepped surface of the second passivation layer 540 shown in FIG. 7 is merely an example and is not intended to be limiting. That is, the shape of the second passivation layer 540 is not limited to that in FIG. 7. In some embodiments, the corners of the stepped surface of the second passivation layer 540 may be acute angles, right angles, rounded angles, obtuse angles, or any suitable shapes. In some embodiments, the second passivation layer 540 may have any shapes corresponding to the height difference of the surface of the first passivation layer 530, that is, the second passivation layer 540 may have a shape corresponding to the step.

In some embodiments, the second passivation layer 540 may be formed by a deposition process, such as low-pressure chemical vapor deposition (LPCVD), atomic layer deposition, molecular beam epitaxy (MBE), other suitable processes, or a combination thereof. In some embodiments, the second passivation layer 530 may be deposited at a temperature from 350° C. to 1200° C., such as 400° C. to 1000° C., 450° C. to 950° C., 500° C. to 900° C., 550° C. to 850° C., 600° C. to 800° C., 650° C. to 750° C., 680° C. to 720° C., 690° C. to 700° C., etc. Even if the second passivation layer 540 is formed at higher temperature, due to the formation of the first passivation layer 530, the gate metal 520 will not be oxidized and the electrical properties of the semiconductor device 10 will not be affected.

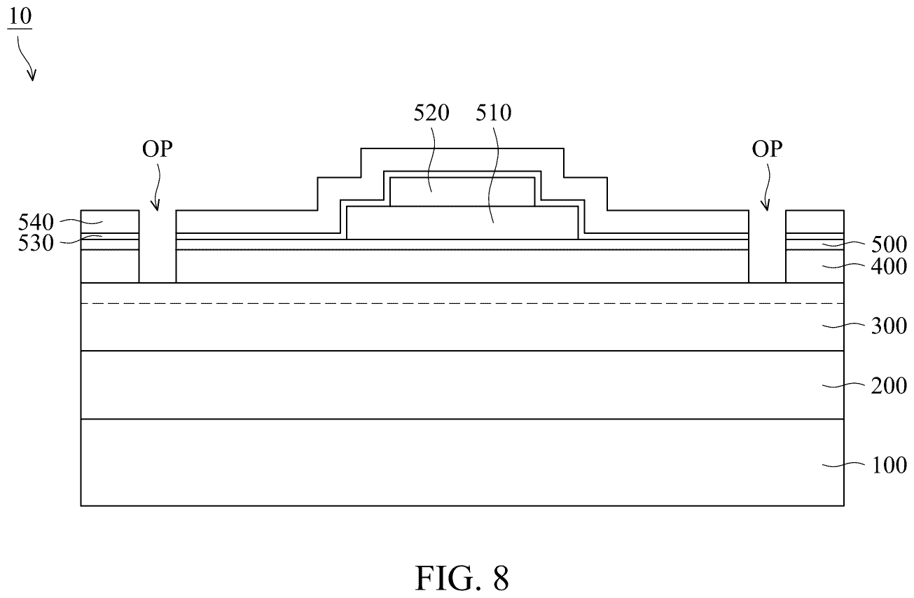

Referring to FIG. 8, the opening OP penetrating the second passivation layer 540, the first passivation layer 530, the first compound semiconductor layer 500 and the barrier layer 400 may be formed through a patterning process. Openings OP may be formed on both sides of the gate metal 520. In some embodiments, contact openings OP may extend into channel layer 300. The contact opening OP is used to form source/drain electrodes. For example, the above-mentioned patterning process may include a photolithography process, an etching process, another appropriate process, or a combination thereof. For details, refer to the patterning of the second compound semiconductor material layer 510a, which will not be repeated herein.

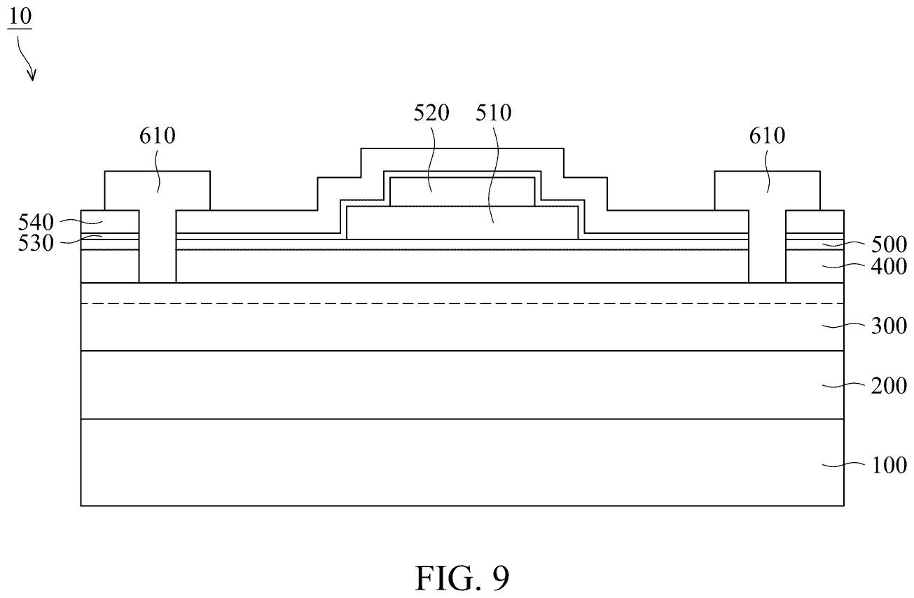

Referring to FIG. 9, source/drain electrodes 610 are formed in the two openings OP. The material of the source/drain electrodes 610 include conductive materials, such as aluminum, copper, tungsten, titanium, tantalum, titanium nitride, tantalum nitride, nickel silicide, cobalt silicide, tantalum carbide, tantalum silicon nitride, tantalum carbonitride, titanium aluminide, titanium aluminum nitride, metal oxides, metal alloys, other suitable conductive materials, or a combination thereof. In addition, the shape of the pair of source/drain electrodes 610 is not limited to the vertical sidewalls as shown in the figure, and may also be tapered sidewalls or have other profiles. The material of the source/drain electrodes 610 may be the same as or different from the material of the gate metal 520.

In some embodiments, the conductive material is deposited in the opening OP by chemical vapor deposition, physical vapor deposition (such as evaporation or sputtering), electroplating, atomic layer deposition, another appropriate method, or a combination thereof. Then a patterning process is performed on the deposited conductive material to form the source/drain electrodes 610 disposed on both sides of the gate metal 520 and in contact with the channel layer 300.

Next, contacts of the gate metal 520 and the source/drain electrodes 610 may be further formed as needed. For example, following FIG. 9, a dielectric layer is formed on the semiconductor device 10, then the dielectric layer is patterned to form contact openings corresponding to the gate metal 520 and the source/drain electrodes 610, and finally the metal material is deposited in the contact openings. to form the contacts.

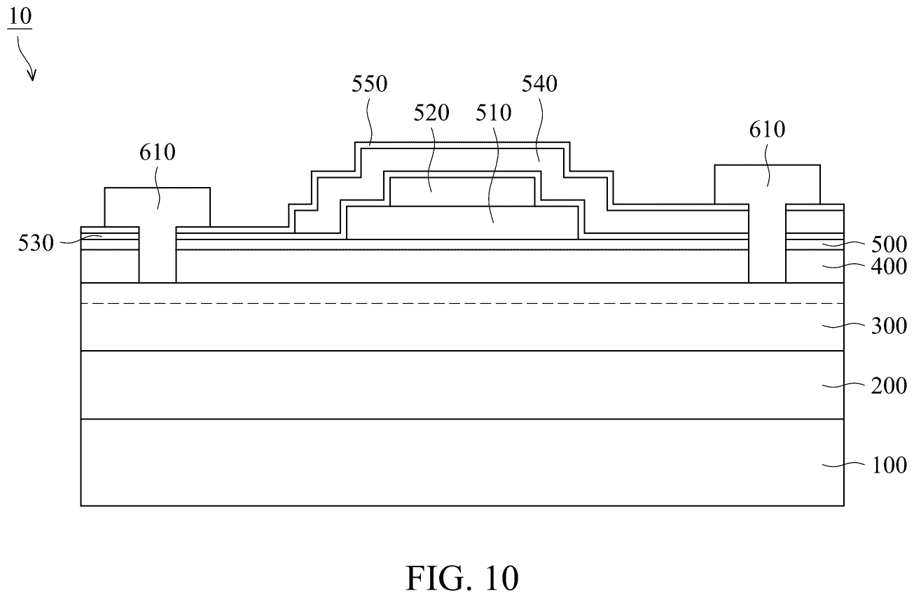

In other embodiments, a third passivation layer 550 may be further formed on the second passivation layer 540. Referring to FIG. 10, which follows FIG. 7, by patterning the second passivation layer 540, a portion of the surface of the first passivation layer 530 is exposed on one side or both sides of the gate metal 520. In some embodiments, the surface of the first passivation layer 530 is exposed closer to the subsequently formed drain electrode. In some embodiments, the surface of the first passivation layer 530 is exposed closer to the subsequently formed source electrode. The ratio of the exposed portion to the unexposed portion of the first passivation layer 530 on one the side of the gate metal 520 can be adjusted as required. Next, a third passivation layer 550 is formed on the first passivation layer 530 and the second passivation layer 540, wherein the third passivation layer 550 is in direct contact with the exposed first passivation layer 530, and the passivation layer 530 may be used as a nucleation layer for the third passivation layer 550.

The third passivation layer 550 may include, for example, silicon oxide (SiOₓ), silicon nitride (SiₓN_{y}), silicon oxynitride (SiOₓN_{y}), aluminum oxide (AlOₓ), aluminum nitride (AlN), polyimide (PI), benzocyclobutene (BCB), polybenzoxazole (PBO), tetraethoxysilane (TEOS) oxide, phosphosilicate glass (PSG), borophosphosilicate glass (BPSG), gallium nitride, other insulating materials, or a combination thereof. The third passivation layer 550 may have a thickness of 3 Å to 200 Å, such as: 5 Å to 180 Å, 10 Å to 160 Å, 15 Å to 140 Å, 20 Å to 120 Å, 25 Å to 100 Å, 30 Å to 80 Å, 35 Å to 75 Å, 40 Å to 70 Å, 45 Å to 65 Å, 50 Å to 60 Å, etc.

In some embodiments, the third passivation layer 550 may have a flat surface. In some embodiments, the third passivation layer 550 may have a stepped surface. The shape of the stepped surface corresponds to the shape of the first passivation layer 530 and the second passivation layer 540. The stepped surface of the third passivation layer 550 shown in FIG. 10 is merely an example and is not intended to be limiting. By forming the third passivation layer 550 in direct contact with part of the first passivation layer 530, the 2DEG characteristics (such as density, mobility, etc.) between the source and the drain can be enhanced, thereby further reducing the sheet resistance (R_{SH}). In some embodiments, by setting the portion where the first passivation layer 530 contact with the third passivation layer 550 closer to the drain in comparison with the source, a better current improvement can be obtained.

In some embodiments, the third passivation layer 550 can be formed by a deposition process, such as plasma enhanced chemical vapor deposition, low vacuum chemical vapor deposition, atomic layer deposition, high density plasma chemical vapor deposition, molecular beam epitaxy (MBE), other suitable processes, or a combination thereof. In some embodiments, the third passivation layer 550 may be deposited at a temperature from 40° C. to 1200° C., such as 50° C. to 1000° C., 100° C. to 950° C., 150° C. to 900° C., 200° C. to 850° C., 250° C. to 800° C., 250° C. to 750° C., 300° C. to 700° C., 350° C. to 650° C., 400° C. to 600° C., 450° C. to 550° C., 500° C. to 525° C., etc.

Then source/drain electrodes 610 are formed on both sides of the gate metal 520. In some embodiments, the opening for forming the source electrode penetrates through the third passivation layer 550, the second passivation layer 540, the first passivation layer 530, the first compound semiconductor layer 500, and the barrier layer 400. The opening for forming the drain electrode penetrates through the third passivation layer 550, the first passivation layer 530, the first compound semiconductor layer 500, and the barrier layer 400. That is, the opening for forming the drain electrode penetrates through the portion where the first passivation layer 530 contact with the third passivation layer 550 and does not penetrate through the second passivation layer 540. In some embodiments, the opening for forming the source does not penetrate through the second passivation layer 540. In some embodiments, source/drain electrode 610 extends into channel layer 300. In some embodiments, the source is closer to the gate metal 520 in comparison with the drain. The forming processes and materials of the source/drain electrodes 610 can be inferred by analogy from the embodiments described in FIGS. 8-9 and will not be repeated herein.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a buffer layer disposed on the substrate;
a channel layer disposed on the buffer layer;
a barrier layer disposed on the channel layer;
a first compound semiconductor layer disposed on the barrier layer;
a second compound semiconductor layer disposed on the first compound layer;
a gate metal disposed on the second compound semiconductor layer;
a first passivation layer disposed on the first compound semiconductor layer, the second compound semiconductor layer and the gate metal; and
a second passivation layer disposed on the first passivation layer.

2. The device as claimed in claim 1, wherein the first passivation layer comprises aluminum oxide, aluminum nitride, silicon oxide, silicon oxynitride, silicon nitride, or a combination thereof.

3. The device as claimed in claim 1, wherein the first passivation layer has a thickness of 3 Å to 200 Å.

4. The device as claimed in claim 1, wherein the second passivation layer comprises aluminum oxide, hafnium oxide, aluminum nitride, silicon oxide, silicon oxynitride, silicon nitride, or a combination thereof.

5. The device as claimed in claim 1, wherein the second passivation layer has a thickness of 100 Å to 2000 Å.

6. The device as claimed in claim 1, further comprising:
source/drain electrodes disposed on both sides of the gate metal, and the source/drain electrodes penetrate through the second passivation layer, the first passivation layer, the first compound semiconductor layer, and the barrier layer.

7. The device as claimed in claim 1, wherein the first compound semiconductor layer comprises undoped gallium nitride.

8. The device as claimed in claim 1, wherein the second compound semiconductor layer comprises p-type gallium nitride.

9. The device as claimed in claim 1, wherein the metal gate comprises titanium nitride.

10. The device as claimed in claim 1, further comprising:
a third passivation layer, disposed on the first passivation layer and the second passivation layer, wherein the third passivation layer is in direct contact with the first passivation layer on one side of the metal gate.

11. The device as claimed in claim 10, wherein the third passivation layer comprises aluminum oxide, aluminum nitride, silicon oxide, silicon oxynitride, silicon nitride, gallium nitride, or a combination thereof.

12. A method of forming a semiconductor device, comprising:
providing a substrate, wherein a buffer layer, a channel layer, and a barrier layer are sequentially formed on the substrate;
forming a first compound semiconductor layer on the barrier layer;
forming a second compound semiconductor material layer on the first compound semiconductor layer;
etching the second compound semiconductor material layer to form a second compound semiconductor layer;
forming a gate metal on the second semiconductor layer;
forming a first passivation layer on the first compound semiconductor layer, the second compound semiconductor layer, and the gate metal; and
forming a second passivation layer on the first passivation layer.

13. The method as claimed in claim 12, wherein the etching of the second compound semiconductor material layer stops at a surface of the first compound semiconductor layer.

14. The method as claimed in claim 12, wherein the first passivation layer is conformally formed on surfaces of the first compound semiconductor layer, the second compound semiconductor layer, and the gate metal.

15. The method as claimed in claim 12, wherein the formation of the first passivation layer is performed at 400° C. or below.

16. The method as claimed in claim 12, wherein the first passivation layer comprises aluminum oxide, aluminum nitride, silicon oxide, silicon oxynitride, silicon nitride, or a combination thereof.

17. The method as claimed in claim 12, wherein the first passivation layer has a thickness of 3 Å to 200 Å.

18. The method as claimed in claim 12, wherein the second passivation layer is conformally formed on the first passivation layer.

19. The method as claimed in claim 12, wherein the formation of the second passivation layer is performed at 350° C. or above.

20. The method as claimed in claim 12, wherein the second passivation layer comprises aluminum oxide, hafnium oxide, aluminum nitride, silicon oxide, silicon oxynitride, silicon nitride, or a combination thereof.

21. The method as claimed in claim 12, wherein the second passivation layer has thickness of 100 Å to 2000 Å.

22. The method as claimed in claim 12, further comprising:
performing a patterning process on the second passivation layer to expose a part of the surface of the first passivation layer on one side of the gate metal; and
forming a third passivation layer on the second passivation layer and the first passivation layer, wherein the third passivation layer is in direct contact with the first passivation layer on the one side of the metal gate.

23. The method as claimed in claim 12, further comprising:
forming source/drain electrodes on both sides of the metal gate, wherein the source/drain electrodes penetrate through the second passivation layer, the first passivation layer, the first compound semiconductor layer, and the barrier layer.
